(19) United States
(12) Patent Application Publication
(10) Pub. No.: US 2011/0291711 A1
(43) Pub. Date: Dec. 1, 2011

(54) POWER-UP SIGNAL GENERATION APPARATUS AND METHOD

(75) Inventor: Jong Hwan KIM, Ichon-shi (KR)

(73) Assignee: Hynix Semiconductor Inc., Ichon-Shi (KR)

(21) Appl. No.: 12/970,413

(22) Filed: Dec. 16, 2010

(30) Foreign Application Priority Data
May 31, 2010 (KR) 10-2010-0051323

(51) Int. Cl. H03L 7/00

(52) U.S. Cl. 327/143

(57) ABSTRACT

A power-up signal generation apparatus includes: a pre-power-up signal generation unit configured to generate a pre-power-up signal depending on a level of a power supply voltage; and a control unit configured to output the pre-power-up signal as a power-up signal in response to an active signal.

### CROSS-REFERENCES TO RELATED APPLICATION

The present application claims priority under 35 U.S.C. §119(a) to Korean Application No. 10-2010-0051323, filed on May 31, 2010, in the Korean Intellectual Property Office, which is incorporated herein by reference in its entirety as if set forth in full.

### BACKGROUND

1. Technical Field

The present invention relates to a semiconductor apparatus, and more particularly, to a semiconductor apparatus including a power-up signal generation circuit and method of generating such power-up signal.

2. Related Art

A semiconductor memory apparatus may typically be coupled to an external application and enabled by receiving power from the external application. The semiconductor memory apparatus detects the level of the applied power supply voltage and activates a power-up signal when the level of the power supply voltage rises to a specific level (hereinafter, referred to as a detection level) or more. The power-up signal generated in such a manner initializes the internal logic of the semiconductor memory apparatus, and instructs the generation of internal voltages.

A power-up signal generation apparatus generates the above-described power-up signal by detecting an external voltage or internal voltage. A semiconductor apparatus including the power-up signal generation apparatus detects the level of a power supply voltage in a stand-by mode, initializes the internal logic when the level of the power supply voltage rises to a detection level or more, and generates internal voltages. Then, when operating in an active mode, the semiconductor apparatus stores or outputs data according to a read or write command.

FIG. 1 is a block diagram of a conventional power-up signal generation apparatus. As described above, the power-up signal generation apparatus detects a power supply voltage Vdd and activates and outputs a power-up signal pu when the level of the power supply voltage Vdd rises to a detection level or more. The power-up signal generation apparatus may be applied to cases in is which the power supply voltage Vdd is an external voltage applied from the outside of the semiconductor memory apparatus, and to cases in which the power supply voltage Vdd is an internal voltage of the semiconductor memory apparatus. The power-up signal generation apparatus includes a power-up signal generation unit 10 configured to detect the power supply voltage Vdd and generate the power-up signal pu.

The power-up signal is a signal which is capable of initializing the internal logic of the semiconductor memory apparatus and instructing generation of internal voltages. Therefore, the power-up signal generation apparatus should not generate the power-up signal pu in active mode. In an active mode, the level of the applied power supply voltage Vdd has risen to the detection level or more. Therefore, in an operation of an ideal semiconductor memory apparatus, the power-up signal pu is not activated in an active mode. However, since a semiconductor memory apparatus performs a read/write operation in active mode, the use of the power supply voltage Vdd is very frequent. Accordingly, in the case of a semiconductor memory apparatus having low voltage level stability of the power supply voltage Vdd, that is, a low power mesh, the voltage level of the power supply voltage Vdd may temporarily drop to the detection level or less. Furthermore, as semiconductor apparatuses adopt low-power structures, the voltage level of the power supply voltage Vdd tends to gradually decrease. Accordingly, the voltage swing from the detection level to the level of the power supply voltage Vdd also tends to decrease gradually. Therefore, the power-up signal pu may be activated more frequently in active mode. Furthermore, as semiconductor memory apparatuses operate at higher speeds, the relative ratios of power supply voltage noise (Vdd noise) may increase, and detection levels may vary due to a process variation or the like. Furthermore, as the degree of integration of semiconductor memory apparatuses increase, the power mesh of the power supply voltage may become low. Due to the above-described situations, the problem of the power-up signal pu being activated in active mode occurs more frequently.

FIG. 2 is a graph showing the instability of the power supply voltage applied to conventional power-up signal generation apparatuses.

In stand-by mode, the level of the power supply voltage Vdd applied externally rises. When the level of the power supply voltage Vdd rises to the detection level or more (a), the power-up signal generation apparatus generates a power-up signal pu. Then, the level of the power supply voltage Vdd needs to be fixed to a preset level in active mode. However, the level of the power supply voltage Vdd may exhibit instability, due to power supply voltage noise, low power mesh of the power supply voltage Vdd, and reduction in voltage swing between the detection level and the level of the power supply voltage Vdd, as described above. When the level of the power supply voltage Vdd drops to the detection level or less and then rises to the detection level or more (b) and (c), the power-up signal pu is may be activated in active mode in which it should not be activated. In this case, the internal logic of the semiconductor memory apparatus may be initialized to cause a fatal error.

### SUMMARY

In one aspect of the present invention, a power-up signal generation apparatus includes: a pre-power-up signal generation unit configured to generate a pre-power-up signal depending on the level of a power supply voltage; and a control unit configured to output the pre-power-up signal as a power-up signal in response to an active signal.

In another aspect of the present invention, a method for generating a power-up signal includes the steps of: generating a pre-power-up signal depending on a power supply voltage level; and receiving an active mode signal and the pre-power-up signal and generating a power-up signal.

### BRIEF DESCRIPTION OF THE DRAWINGS

Features, aspects, and embodiments are described in conjunction with the attached drawings, in which:

FIG. 1 is a block diagram of a conventional power-up signal generation apparatus;

FIG. 2 is a graph showing instability of a power supply voltage applied to a conventional power-up signal generation apparatus; and

FIG. 3 is a circuit diagram of a power-up signal generation apparatus according to one embodiment.

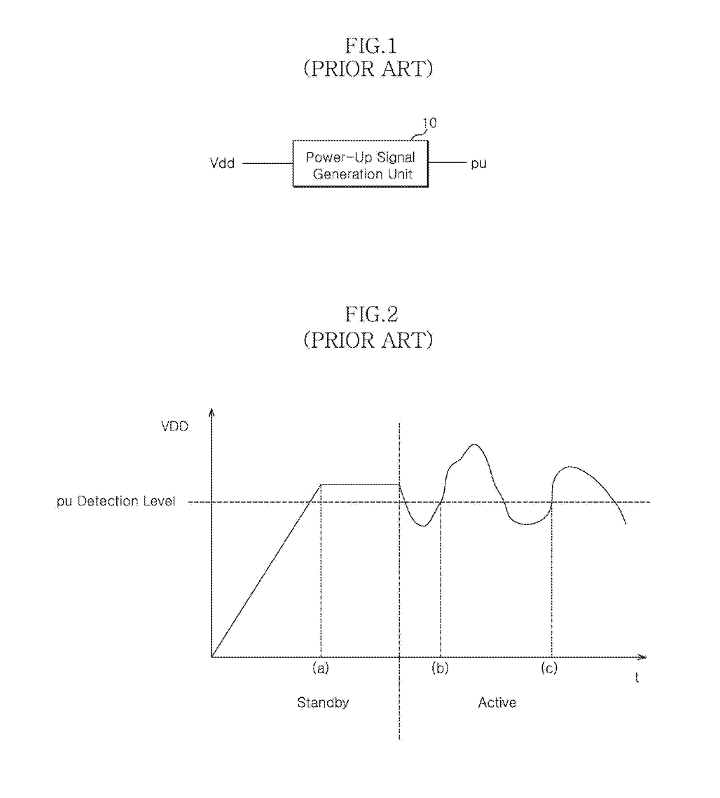

### DETAILED DESCRIPTION

Hereinafter, a power-up signal generation apparatus and method according to the present invention will be described below with reference to the accompanying drawings through exemplary embodiments.

A power-up signal generation apparatus according to one embodiment may solve the above-described problem by activating or deactivating a power-up signal pu depending on whether the semiconductor apparatus is in an active mode and a stand-by mode. In this embodiment, an active signal act, which is activated in an active mode, is used to fix the power-up signal pu to a deactivation state after the active signal act is activated, thereby substantially preventing the power-up signal pu from being unexpectedly activated by the noise of a power supply voltage level. The active signal act is an internal command signal generated inside a semiconductor memory apparatus in response to external commands (for example, RAS and CAS). In the case of DRAM, when the active signal act is activated, a precharge operation for bit lines and bit bar lines is stopped, and an operation for enabling word lines is performed.

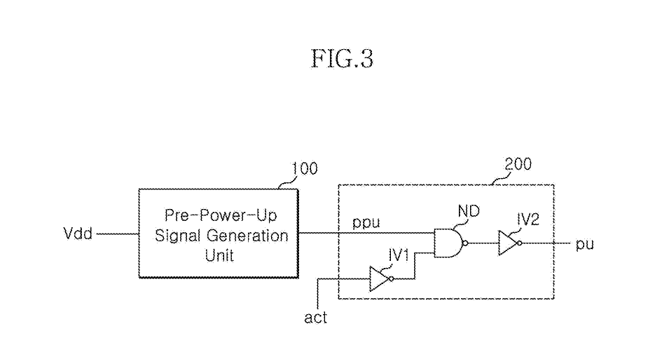

FIG. 3 is a circuit diagram of a power-up signal generation apparatus according to one embodiment.

The power-up signal generation apparatus includes a pre-power-up signal generation unit 100 and a control unit 200. In the power-up signal generation apparatus, the pre-power-up signal generation unit 100 generates a pre-power-up signal ppu depending on a power supply voltage level as a first step, and the control unit 200 outputs the pre-power-up signal ppu as a power-up signal pu or fixes the power-up signal pu to a deactivation state, depending on whether the active signal act is deactivated or not, as a second step.

The pre-power-up signal generation unit 100 is configured to detect the level of the power supply voltage and generate the pre-power-up signal ppu. The pre-power-up signal generation unit 100 may be configured in the same manner as the power-up signal generation unit 10 of a conventional power-up signal generation apparatus, which is illustrated in FIG. 1. While the conventional power-up signal generation apparatus uses the pre-power-up signal ppu as the power-up signal pu, the power-up signal generation apparatus according to the embodiment inputs the pre-power-up signal ppu to the control unit 200, and the control unit 200 generates the power-up signal pu.

The control unit 200 is configured to output the pre-power-up signal ppu as the power-up signal pu in response to the active signal act. The active signal act is a signal for controlling an active mode operation of the semiconductor memory apparatus. The power-up signal generation apparatus illustrated in FIG. 3 may decide an operation mode depending on the active signal act, and activate and output the power-up signal pu according to the decided operation mode. As described above, the power-up signal pu is a signal which initializes the internal logic and generates internal voltages. Therefore, the power-up signal pu should not be activated in an active mode. The control unit 200 fixes the power-up signal pu to a deactivation state in an active mode.

As illustrated in FIG. 3, the control unit 200 may include a first inverter IV1, a second inverter IV2, and a NAND gate ND. The first inverter IV1 is configured to invert and output the active signal act. The NAND gate ND is configured to perform a NAND operation on the pre-power-up signal ppu and the signal outputted from the first inverter IV1. The second inverter IV2 is configured to invert the signal outputted from the NAND gate ND and output the inverted signal as the power-up signal pu. Since the control unit 200 includes the NAND gate ND, the control unit 200 outputs the pre-power-up signal ppu as the power-up pu when the active signal act is deactivated, and fixes the power-up signal pu to a deactivation state, that is, a specific voltage level, when the active signal act is activated.

The power-up signal generation apparatus illustrated in FIG. 3 decides an operation mode depending on the active signal act, and activates and outputs the power-up signal pu according to the operation mode. When operating in a stand-by mode, the power-up signal generation apparatus detects the level of the power supply voltage Vdd and activates and generates the power-up signal pu. When operating in an active mode, the power-up signal generation apparatus fixes the power-up signal pu to a deactivation state, that is, is a specific level, regardless of the level of the power supply voltage Vdd.

In a conventional power-up signal generation apparatus, the power-up signal pu may be unexpectedly activated due to the instability of the power supply voltage Vdd in an active mode, possibly resulting in a fatal error. In the power-up signal generation apparatus, however, the power-up signal pu is maintained at the deactivation state in an active mode. Therefore, although the power supply voltage Vdd varies unstably in an active mode, the semiconductor apparatus operates normally.

While certain embodiments have been described above, it will be understood to those skilled in the art that the embodiments described are by way of example only. Accordingly, the power-up signal generation apparatus and method described herein should not be limited based on the described embodiments. Rather, the power-up signal generation apparatus and method described herein should only be limited in light of the claims that follow when taken in conjunction with the above description and accompanying drawings.

What is claimed is:

1. A power-up signal generation apparatus comprising:
a pre-power-up signal generation unit configured to generate a pre-power-up signal depending on a level of a power supply voltage; and
a control unit configured to output the pre-power-up signal as a power-up signal in response to an active signal.

2. The power-up signal generation apparatus according to claim 1, wherein, when the active signal is deactivated, the control unit outputs the pre-power-up signal as the power-up signal.

3. The power-up signal generation apparatus according to is claim 1, wherein, when the active signal is activated, the control unit fixes the power-up signal to a deactivation state.

4. A method for generating a power-up signal, comprising the steps of:
generating a pre-power-up signal depending on the level of a power supply voltage; and
receiving an active mode signal and a pre-power-up signal and generating a power-up signal.

5. The method according to claim 4, wherein, in the step of receiving the active mode signal and the pre-power-up signal, when the active mode signal is deactivated, the pre-power-up signal is outputted as the power-up signal.

6. The method according to claim 4, wherein, in the step of receiving the active mode signal and the pre-power-up signal, when the active mode signal is activated, the power-up signal is fixed to a deactivation state.
